(19) United States
(12) Patent Application Publication
(10) Pub. No.: US 2024/0221855 A1
(43) Pub. Date: Jul. 4, 2024

(54) MEMORY DEVICE AND TEST METHOD THEREOF

(71) Applicant: MACRONIX International Co, Ltd., Hsinchu (TW)

(72) Inventors: Chih-Wei Hu, Miaoli County (TW); Teng Hao Yeh, Hsinchu County (TW); Hang-Ting Lue, Hsinchu (TW)

(73) Assignee: MACRONIX International Co, Ltd., Hsinchu (TW)

(21) Appl. No.: 18/149,676

(22) Filed: Jan. 4, 2023

(51) Int. Cl. G11C 29/12; G11C 16/26

(52) U.S. Cl. CPC G11C 29/1201; G11C 16/26; G11C 2029/1204

(57) ABSTRACT

A memory device and a test method thereof are provided. The memory device (e.g., a 3D stack AND type flash memory) includes a memory cell array, a first global bit line, a second global bit line, and a switch component. The memory cell array is divided into a first memory cell group and a second memory cell group. The first memory cell group has a plurality of first local bit lines and a plurality of first local source lines, and the second memory cell group has a plurality of second local bit lines and a plurality of second local source lines. The switch component is configured to couple the first local source lines to a common source line or couple the second local source lines to the common source line during a plurality of different test modes.

### BACKGROUND

### Technical Field

The disclosure relates to a memory device and a test method thereof, and in particular, relates to a memory device and a test method for testing short circuits between source lines and bit lines.

### Description of Related Art

With the advancement of electronic technology, the storage density of memory devices also increases. At present, memory cell arrays often have a large number of local bit lines and local source lines. These local bit lines and local source lines are usually arranged in an alternating manner and may be shorted to each other.

In a memory device, short circuits between local bit lines and local source lines may occur in the same memory cell group or between adjacent memory cell groups. In the related art, when a short circuit is detected between the local bit line and the local source line, it cannot be identified whether the short circuit occurs in the same memory cell group or between adjacent memory cell groups most of the time, and therefore correct repair actions cannot be performed.

### SUMMARY

The disclosure provides a memory device and a test method thereof through which a short circuit between a local bit line and a local source line between adjacent groups is effectively tested.

The disclosure provides a memory device (e.g., a 3D stack AND type flash memory) includes a memory cell array, a first global bit line, a second global bit line, and a switch component. The memory cell array is divided into a first memory cell group and a second memory cell group. The first memory cell group has a plurality of first local bit lines and a plurality of first local source lines, and the second memory cell group has a plurality of second local bit lines and a plurality of second local source lines. The first global bit line and a second global bit line are respectively coupled to a first sense amplifier and a second sense amplifier. The first global bit line is coupled to the first local bit lines. The second global bit line is coupled to the second local bit lines. A switch component is coupled among the first local source lines, the second local source lines, and a common source line. The switch component is configured to couple the first local source lines to the common source line or couple the second local source lines to the common source line during a plurality of different test modes.

The disclosure further provides a test method, and the test method includes the following steps. A memory cell array is divided into a first memory cell group and a second memory cell group. The first memory cell group has a plurality of first local bit lines and a plurality of first local source lines, and the second memory cell group has a plurality of second local bit lines and a plurality of second local source lines. A first global bit line and a second global bit line are respectively coupled to a first sense amplifier and a second sense amplifier. The first global bit line is coupled to the first local bit lines, and the second global bit line is coupled to the second local bit lines. A switch component is arranged among the first local source lines, the second local source lines, and a common source line. During a plurality of different test modes, the first local source lines are coupled to the common source line or the second local source lines are coupled to the common source line.

To sum up, in the memory device provided by the disclosure, through the switch component, the first local source lines or the second local source lines are coupled to the common source line, so as to respectively test a short circuit between the local bit lines and the local source lines in the same memory cell group and test a short circuit between the local bit lines and the local source lines in adjacent memory cell groups. In this way, in the memory cell array, the short circuit test between the local bit lines and the local source lines can be effectively completed, and the normal operation of the memory device is maintained.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a memory device according to an embodiment of the disclosure.

FIG. 2 illustrates a schematic structural diagram of a memory device according to an embodiment of the disclosure.

FIG. 3 illustrates a test flow chart of the memory device according to an embodiment of the disclosure.

FIG. 4A to FIG. 4C illustrate schematic diagrams of test operations performed in the memory device according to an embodiment of the disclosure.

FIG. 5 illustrates a schematic diagram of a memory cell structure of the memory device according to an embodiment of the disclosure.

FIG. 6 illustrates a flow chart of a test method of the memory device according to an embodiment of the disclosure.

### DESCRIPTION OF THE EMBODIMENTS

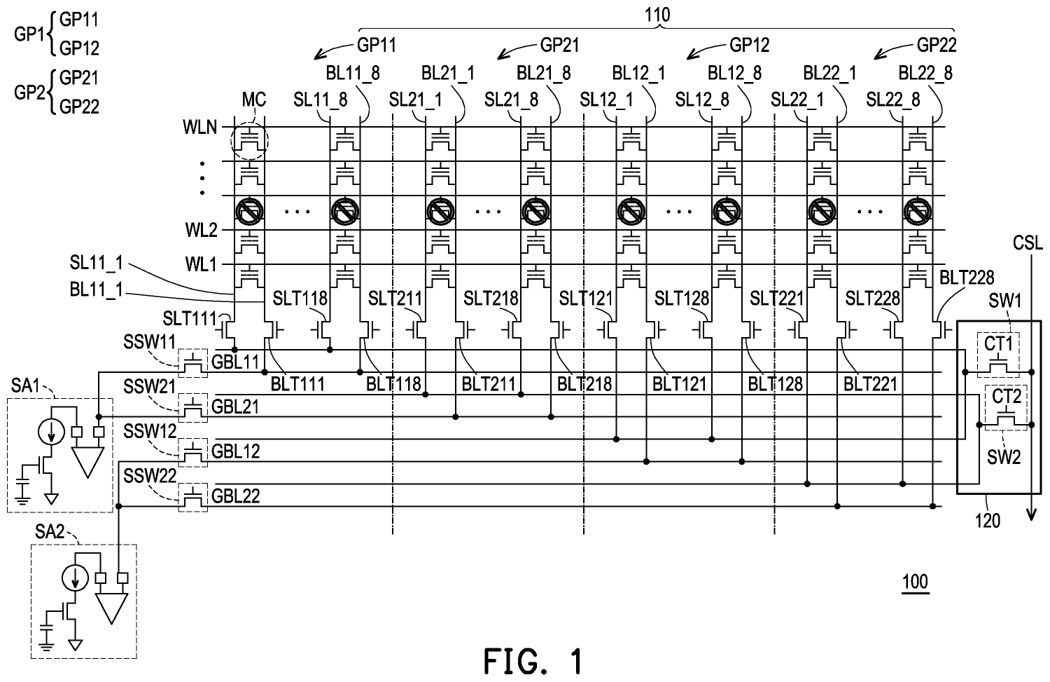

With reference to FIG. 1, FIG. 1 illustrates a schematic diagram of a memory device according to an embodiment of the disclosure. A memory device 100 includes a memory cell array 110, first global bit lines GBL11 and GBL21, second global bit lines GBL12 and GBL22, sense amplifiers SA1 and SA2, and a switch component 120. The memory cell array 110 has a plurality of flash memory cells MC. The memory cell array 110 is divided into a first memory cell group GP1 and a second memory cell group GP2. The first memory cell group may be further divided into memory cell subgroups GP11 and GP12, and the second memory cell group may be further divided into memory cell subgroups GP21 and GP22. In this embodiment, the memory cell subgroup GP11 includes local source lines SL11_1 to SL11_8 and local bit lines BL11_1 to BL11_8. The memory cell subgroup GP21 includes local source lines SL21_1 to SL21_8 and local bit lines BL21_1 to BL21_8. The memory cell subgroup GP12 includes local source lines SL12_1 to SL12_8 and local bit lines BL12_1 to BL12_8. The memory cell subgroup GP21 has local source lines SL22_1 to SL22_8 and local bit lines BL22_1 to BL22_8.

In addition, the local source lines SL11_1 to SL11_8 and the local source lines SL12_1 to SL12_8 are coupled to the switch component 120 respectively through source line switches SLT111 to SLT118 and SLT121 to SLT128. The local source lines SL21_1 to SL21_8 and the local source lines SL22_1 to SL22_8 are coupled to the switch component 120 respectively through source line switches SLT211 to SLT218 and SLT221 to SLT228. The local bit lines BL11_1 to BL11_8 are coupled to the global bit line GBL11 through bit line switches BLT111 to BLT118. The local bit lines BL21_1 to BL21_8 are coupled to the global bit line GBL21 through bit line switches BLT211 to BLT218. The local bit lines BL12_1 to BL12_8 are coupled to the global bit line GBL12 through bit line switches BLT121 to BLT128. The local bit lines BL22_1 to BL22_8 are coupled to the global bit line GBL22 through bit line switches BLT221 to BLT228.

The abovementioned source line switches SLT111 to SLT228 and the bit line switches BLT111 to BLT228 may both be transistor switches.

The sense amplifier SA1 is coupled to the global bit lines GBL11 and GBL21 respectively through selection switches SSW11 and SSW21. The sense amplifier SA2 is coupled to the global bit lines GBL21 and GBL22 respectively through selection switches SSW12 and SSW22.

On the other hand, the switch component 120 includes switches SW1 and SW2 constructed by transistors. A first end of the switch SW1 is coupled to the source line switches SLT111 to SLT118 and SLT121 to SLT128, and the first end of the switch SW1 is coupled to a common source line CSL. A first end of the switch SW2 is coupled to the source line switches SLT211 to SLT218 and SLT221 to SLT228, and the first end of the switch SW2 is coupled to the common source line CSL. The switches SW1 and SW2 are controlled by test mode signals CT1 and CT2, respectively.

In the embodiments of the disclosure, in the memory device 100, when a test operation is performed to check whether a short circuit occurs between the local bit lines BL11_1 to BL22_8 and the local source lines SL11_1 to SL22_8, all the memory cells MC in the memory cell array 110 are cut-off through received word line voltages WL1 to WLN. Besides, through the on or off state of each of the source line switches SLT111 to SLT228 and the bit line switches BLT111 to BLT228, the local bit line under test and the local source line under test may be selected. The sense amplifiers SA1 and SA2 may obtain the test result by sensing whether leakage occurs on the coupled global bit line.

It should be noted that in the abovementioned test operation, the switch component 120 may use the on or off state of the switch SW1 to couple the local source lines SL11_1 to SL11_8 and SL12_1 to SL12_8 to the common source line CSL to receive a common source voltage or be in a floating state. The switch component 120 may also use the on or off state of the switch SW2 to couple the local source lines SL21_1 to SL21_8 and SL22_1 to SL22_8 to the common source line CSL to receive the common source voltage or be in a floating state. In this embodiment, the common source voltage may be any set voltage value, for example, 0 volts.

In detail, with the on and off states of the source line switches SLT111 to SLT118 and SLT121 to SLT128, when the switch component 120 enables one of the local source lines SL11_1 to SL11_8 and one of the SL12_1 to SL12_8 to receive the common source voltage (0 volts), the switch component 120 may make the local source lines SL21_1 to SL21_8 and SL22_1 to SL22_8 in a floating state. Herein, with the on and off states of the bit line switches BLT111 to BLT118 and BLT121 to BLT128 and the on states of the selection switches SSW11 and SSW12, one of the local bit lines BL11_1 to BL11_8 and one of the BL12_1 to BL12_8 may be respectively coupled to the global bit line GBL11 and GBL12 and are coupled to the sense amplifiers SA1 and SA2 respectively through the selection switches SSW11 and SSW12. In this way, the sense amplifier SA1 may detect whether there is a short circuit between the local bit lines BL11_1 to BL11_8 and the local source lines SL11_1 to SL11_8 in the memory cell subgroup GP11 by sensing whether there is leakage current on the global bit line GBL11. The sense amplifier SA2 may detect whether there is a short circuit between the local bit lines BL12_1 to BL12_8 and the local source lines SL12_1 to SL12_8 in the memory cell subgroup GP12 by sensing whether there is leakage current on the global bit line GBL12.

It is worth mentioning that when the test result indicates that there is a short circuit between the local bit lines BL11_1 to BL11_8 and BL12_1 to BL12_8 and the local source lines SL11_1 to SL11_8 and SL12_1 to SL12_8, a replacement operation may be performed on the memory cell string in which the short circuit occurs, and the erroneous state may be effectively eliminated.

Next, with the on and off states of the source line switches SLT211 to SLT218 and SLT221 to SLT228, when the switch component 120 enables one of the local source lines SL21_1 to SL21_8 and one of the SL22_1 to SL22_8 to receive the common source voltage (0 volts), the switch component 120 may make the local source lines SL11_1 to SL11_8 and SL12_1 to SL12_8 in a floating state. Herein, with the on and off states of the bit line switches BLT111 to BLT118 and BLT121 to BLT128 and the on states of the selection switches SSW11 and SSW12, one of the local bit lines BL11_1 to BL11_8 and one of the BL12_1 to BL12_8 may be respectively coupled to the global bit line GBL11 and GBL12 and are coupled to the sense amplifiers SA1 and SA2 respectively through the selection switches SSW11 and SSW12. In this way, the sense amplifier SA1 may detect whether there is a short circuit between the local bit lines BL21_1 to BL21_8 and the local source lines SL21_1 to SL21_8 in the memory cell subgroup GP21 by sensing whether there is leakage current on the global bit line GBL21. The sense amplifier SA2 may detect whether there is a short circuit between the local bit lines BL22_1 to BL22_8 and the local source lines SL22_1 to SL22_8 in the memory cell subgroup GP22 by sensing whether there is leakage current on the global bit line GBL22.

It is worth mentioning that when the test result indicates that there is a short circuit between the local bit lines BL21_1 to BL21_8 and BL22_1 to BL22_8 and the local source lines SL21_1 to SL21_8 and SL22_1 to SL22_8, a replacement operation may be performed on the memory cell string in which the short circuit occurs, and the erroneous state may be effectively eliminated.

Through the above test operations, the short circuit in the same memory cell groups GP1 and GP2 may be effectively eliminated, and the short circuit between the memory cell groups GP1 and GP2 may then be tested. Herein, with the on and off states of the source line switches SLT211 to SLT218 and SLT221 to SLT228, the switch component 120 enables one of the local source lines SL21_1 to SL21_8 arranged on the edge of the memory cell subgroup GP21 to receive the common source voltage (0 volts) and enables one of the local source lines SL22_1 to SL22_8 arranged on the edge of the memory cell subgroup GP22 to receive the common source voltage (0 volts). The switch component 120 may also make the local source lines SL11_1 to SL11_8 and SL12_1 to SL12_8 in a floating state. Herein, with the on and off states of the bit line switches BLT111 to BLT118 and BLT121 to BLT128 and the on states of the selection switches SSW11 and SSW12, one of the local bit lines BL11_1 to BL11_8 arranged on the edge of the memory cell subgroup GP11 may be coupled to the global bit line GBL11, one of the local bit lines BL12_1 to BL12_8 arranged on the edge of the memory cell subgroup GP12 may be coupled to the global bit line GBL11, and the two are coupled to the sense amplifiers SA1 and SA2 respectively through the selection switches SSW11 and SSW12.

In this way, the sense amplifier SA1 may detect whether there is a short circuit between the local bit lines BL11_1 to BL11_8 in the memory cell subgroup GP11 and the local source lines SL21_1 to SL21_8 in the memory cell subgroup GP21 by sensing whether there is leakage current on the global bit line GBL11. The sense amplifier SA2 may detect whether there is a short circuit among the local bit lines BL12_1 to BL12_8 in the memory cell subgroup GP12, the local source lines SL22_1 to SL22_8 in the memory cell subgroup GP22, and the local source lines SL21_1 to SL21_8 in the memory cell subgroup GP21 by sensing whether there is leakage current on the global bit line GBL12.

That is, the short circuit between the adjacent memory cell groups GP1 and GP2 may also be effectively detected. Further, the replacement operation may be performed on the short-circuited memory cell string, so that the erroneous state may be effectively eliminated.

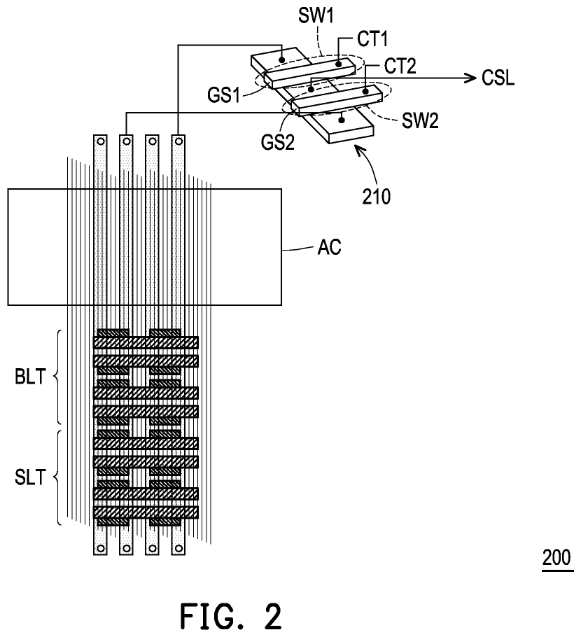

With reference to FIG. 2, FIG. 2 illustrates a schematic structural diagram of a memory device according to an embodiment of the disclosure. A memory device 200 is a 3D stack memory and includes a memory cell area AC, a bit line switch BLT, a source line switch SLT, and a switch component 210. The memory cell area AC is configured to set up a plurality of memory cells and form a memory cell array. The bit line switch BLT and the source line switch SLT are a plurality of transistor switches. The switch component 210 has switches SW1 and SW2, which are also transistor switches. Herein, the switch SW1 has a gate structure GS1, one end of the switch SW1 is coupled to the global bit line CLS, and the other end of the switch SW1 may be coupled to a source line GSL_n+1. Herein, the source line GSL_n+1 is coupled to some of the source line switches SLT. The switch SW2 has a gate structure GS2, one end of the switch SW2 is coupled to the global bit line CLS, and the other end of the switch SW2 may be coupled to source lines GSL_n. Herein, the source line GSL_n is coupled to the rest of the source line switches SLT.

The gate structure GS1 receives the test mode signal CT1, and the gate structure GS2 receives the test mode signal CT2. The switches SW1 and SW2 may be turned on or off according to the test mode signals CT1 and CT2, respectively. The source line GSL_n+1 may be coupled to the common source line CSL when the switch SW1 is turned on, and the source line GSL_n may be coupled to the common source line CSL when the switch SW2 is turned on. In this embodiment, in the test mode, one of the switches SW1 and SW2 may be turned on, and the other one may be turned off.

Incidentally, in the memory device 200, the global bit line GBL_n may be coupled to some of the bit line switches BLT, and the global bit line GBL_n+1 may be coupled to the rest of the bit line switches BLT.

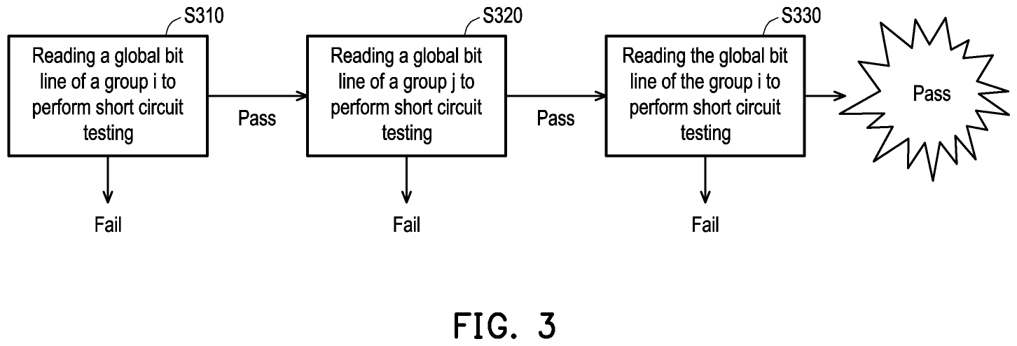

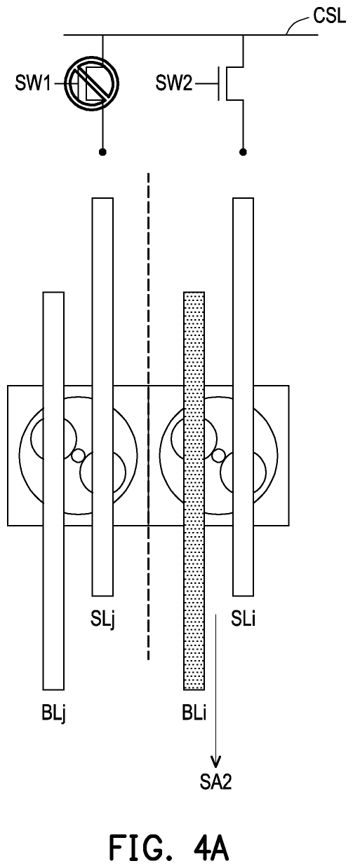

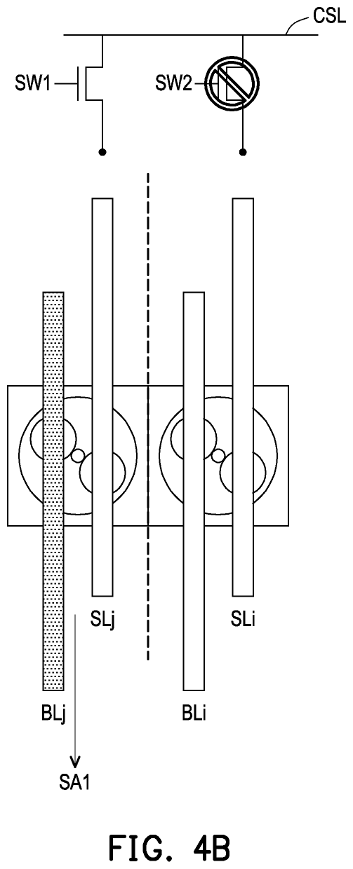

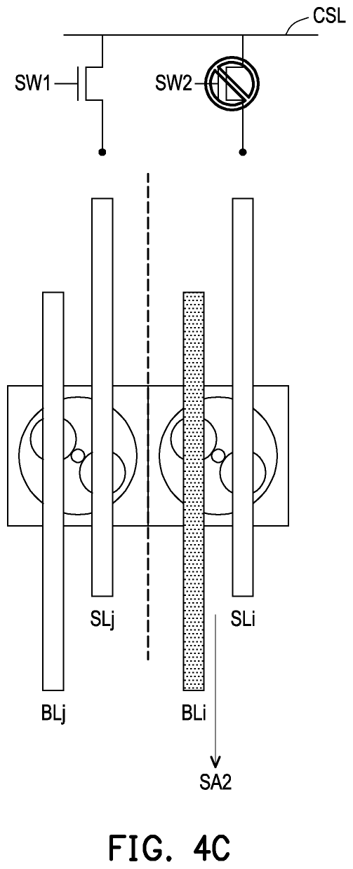

With reference to FIG. 3 and FIG. 4A to FIG. 4C, FIG. 3 illustrates a test flow chart of the memory device according to an embodiment of the disclosure, and FIG. 4A to FIG. 4C illustrate schematic diagrams of test operations performed in the memory device according to an embodiment of the disclosure. In FIG. 3, in step S310, corresponding to FIG. 4A, the switch SW1 connected to a local source line SLj is turned off, and the local source line SLj is floated, wherein the local source line SLj and a common bit line Blj are coupled to a same memory cell. The switch SW2 connected to a local source line SLi is turned on, and the local source line SLi is coupled to the common source line CSL to receive the common source voltage (e.g., 0 volts). The sense amplifier SA2 may perform a read test on a global bit line BLi, and when detecting that there is leakage current on the global bit line BLi, the sense amplifier SA2 indicates that the test fails and indicates that there is a short circuit between the local source line SLi and the bit line corresponding to the global bit line BLi.

When the test fails, a replacement operation may be performed on the memory cell string of the short-circuited local source line SLi.

If the result of the test in step S310 is pass, step S320 may be executed.

In step S320, corresponding to FIG. 4B, the switch SW2 connected to the local source line SLi is turned off, and the local source line SLi is floated. The switch SW1 connected to a local source line SLj is turned on, and the local source line SLj is coupled to the common source line CSL to receive the common source voltage (e.g., 0 volts). The sense amplifier SA1 may perform a read test on a global bit line BLj, and when detecting that there is leakage current on the global bit line BLj, the sense amplifier SA1 indicates that the test fails and indicates that there is a short circuit between the local source line SLj and the bit line corresponding to the global bit line BLj.

When the test fails, a replacement operation may be performed on the memory cell string of the short-circuited local source line SLj.

If the result of the test in step S320 is pass, step S330 may be executed.

In step S330, corresponding to FIG. 4C, the switch SW2 connected to the local source line SLi is turned off, and the local source line SLi is floated. The switch SW1 connected to the local source line SLj is turned on, and the local source line SLj is coupled to the common source line CSL to receive the common source voltage (e.g., 0 volts). The sense amplifier SA2 may perform a read test on a global bit line BLi, and when detecting that there is leakage current on the global bit line BLi, the sense amplifier SA2 indicates that the test fails and indicates that there is a short circuit between the local source line SLj and the bit line corresponding to the global bit line BLi.

When the test fails, a replacement operation may be performed on the memory cell string of the short-circuited local source line SLi.

If the result of the test in step S330 is pass, it means that the short circuit test of the circuit of the memory device is passed.

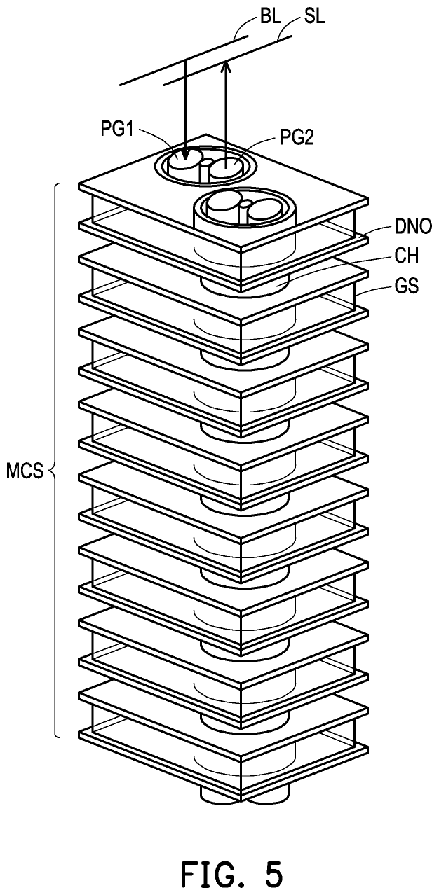

With reference to FIG. 5, FIG. 5 illustrates a schematic diagram of a memory cell structure of the memory device according to an embodiment of the disclosure. In the embodiments of the disclosure, a plurality of memory cells MCs in the memory device are constructed in a stacked manner, and form a memory cell string with a three-dimensional structure. Each memory cell may have a silicon oxide-silicon nitride-silicon oxide layer ONO as an insulating layer. Each memory cell has a channel structure CH and a gate structure GS. A local bit line BL and a local source line SL are respectively connected to all the memory cells MCs in the memory cell string through conductive pins PG1 and PG2.

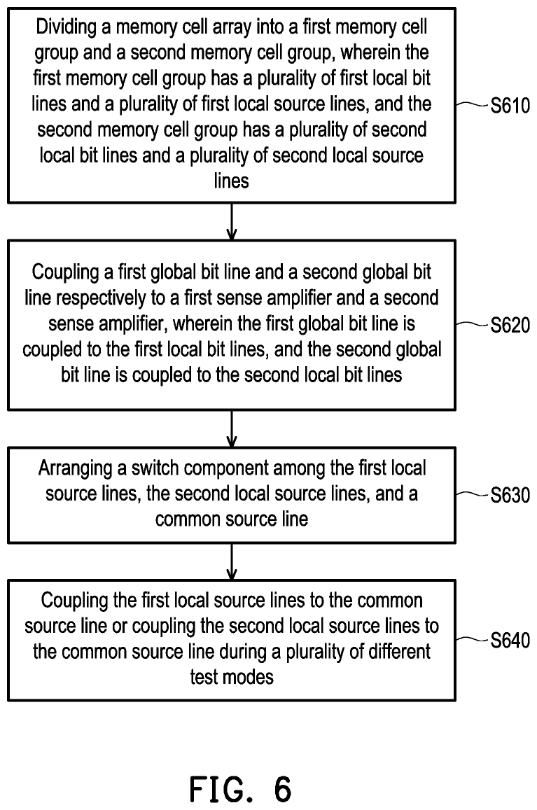

With reference to FIG. 6, FIG. 6 illustrates a flow chart of a test method of the memory device according to an embodiment of the disclosure. In step S610, the memory cell array is divided into a first memory cell group and a second memory cell group. The first memory cell group has a plurality of first local bit lines and a plurality of first local source lines, and the second memory cell group has a plurality of second local bit lines and a plurality of second local source lines. In step S620, a first global bit line and a second global bit line are respectively coupled to a first sense amplifier and a second sense amplifier. The first global bit line is coupled to the first local bit lines, and the second global bit line is coupled to the second local bit lines. Further, in step S630, a switch component is arranged among the first local source lines, the second local source lines, and a common source line. In step S640, during a plurality of different test modes, the first local source lines are coupled to the common source line, or the second local source lines are coupled to the common source line.

The operation details of the above steps are described in detail in the foregoing embodiments, and description thereof is not to be repeated herein.

In view of the foregoing, in the memory device provided by the disclosure, the switch component is arranged between the common source line and local source lines. In the test mode, the switch component is used to float the local source lines in one memory cell group and couple the local source lines in another memory cell group to the common source line. Further, the read operation is performed for the global bit line through the sense amplifiers corresponding to different memory cell groups. According to whether there is leakage current on the global bit line, whether there is a short circuit between the regional source lines and the local bit lines in the same or adjacent memory cell groups can be detected, and the memory cell array may be maintained to work normally.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device, comprising:
a memory cell array, divided into a first memory cell group and a second memory cell group, wherein the first memory cell group has a plurality of first local bit lines and a plurality of first local source lines, and the second memory cell group has a plurality of second local bit lines and a plurality of second local source lines;
a first global bit line and a second global bit line, respectively coupled to a first sense amplifier and a second sense amplifier, wherein the first global bit line is coupled to the first local bit lines, and the second global bit line is coupled to the second local bit lines; and
a switch component, coupled among the first local source lines, the second local source lines, and a common source line, configured to couple the first local source lines to the common source line or couple the second local source lines to the common source line during a plurality of different test modes.

2. The memory device according to claim 1, wherein in a first test mode, the switch component couples the first local source lines to the common source line and cuts off a coupling between the second local source lines and the common source line.

3. The memory device according to claim 2, wherein in the first test mode, the first sense amplifier tests whether a short circuit occurs between each of the first local source lines and each of the first local bit lines.

4. The memory device according to claim 2, wherein in a second test mode, the switch component couples the second local source lines to the common source line and cuts off a coupling between the first local source lines and the common source line.

5. The memory device according to claim 4, wherein in the second test mode, the second sense amplifier tests whether a short circuit occurs between each of the second local source lines and each of the second local bit lines.

6. The memory device according to claim 4, wherein in a third test mode, the switch component couples the second local source lines to the common source line and cuts off the coupling between the first local source lines and the common source line, and the second sense amplifier tests whether a short circuit occurs between each of the first local source lines and each of the second local bit lines.

7. The memory device according to claim 1, wherein the switch component comprises:
a first switch, having a first end coupled to the first local source lines, wherein a second end of the first switch is coupled to the common source line; and
a second switch, having a first end coupled to the second local source lines, wherein a second end of the second switch is coupled to the common source line,
wherein the first switch and the second switch are respectively controlled by a first test mode signal and a second test mode signal.

8. The memory device according to claim 1, further comprising:
a plurality of first bit line switches, coupled between the first global bit line and the first local bit lines; and
a plurality of second bit line switches, coupled between the second global bit line and the second local bit lines.

9. The memory device according to claim 8, further comprising:
a first selection switch, coupled between the first global bit line and the first sense amplifier; and
a second selection switch, coupled between the second global bit line and the second sense amplifier.

10. The memory device according to claim 1, further comprising:
a plurality of first source line switches, coupled between the switch component and the first local source lines; and
a plurality of second source line switches, coupled between the switch component and the second local source lines.

11. The memory device according to claim 1, wherein in the test modes, a plurality of memory cells in the first memory cell group and the second memory cell group are in an access-prohibited state.

12. A test method of a memory device, comprising:
dividing a memory cell array into a first memory cell group and a second memory cell group, wherein the first memory cell group has a plurality of first local bit lines and a plurality of first local source lines, and the second memory cell group has a plurality of second local bit lines and a plurality of second local source lines;
coupling a first global bit line and a second global bit line respectively to a first sense amplifier and a second sense amplifier, wherein the first global bit line is coupled to the first local bit lines, and the second global bit line is coupled to the second local bit lines;
arranging a switch component among the first local source lines, the second local source lines, and a common source line; and
coupling the first local source lines to the common source line or coupling the second local source lines to the common source line during a plurality of different test modes.

13. The test method according to claim 12, comprising:
in a first test mode, coupling the first local source lines to the common source line and cutting off a coupling between the second local source lines and the common source line by the switch component.

14. The test method according to claim 13, further comprising:
in the first test mode, testing, by the first sense amplifier, whether a short circuit occurs between each of the first local source lines and each of the first local bit lines.

15. The test method according to claim 13, further comprising:
in a second test mode, coupling the second local source lines to the common source line and cutting off a coupling between the first local source lines and the common source line by the switch component.

16. The test method according to claim 15, further comprising:
in the second test mode, testing, by the second sense amplifier, whether a short circuit occurs between each of the second local source lines and each of the second local bit lines.

17. The test method according to claim 15, further comprising:
in a third test mode, coupling the second local source lines to the common source line and cutting off the coupling between the first local source lines and the common source line by the switch component; and
testing, by the second sense amplifier, whether a short circuit occurs between each of the first local source lines and each of the second local bit lines.

18. The test method according to claim 12, further comprising:
in the test modes, a plurality of memory cells in the first memory cell group and the second memory cell group are in a cut-off state.
